(19) United States
(12) Patent Application Publication
(10) Pub. No.: US 2011/0069461 A1
(43) Pub. Date: Mar. 24, 2011

(54) CARD GUIDE MISALIGNMENT PREVENTION APPARATUSES AND METHODS

(76) Inventor: Bennie M. Childs, JR., Mesquite, TX (US)

(21) Appl. No.: 12/721,516

(22) Filed: Mar. 10, 2010

Related U.S. Application Data
(60) Provisional application No. 61/243,996, filed on Sep. 18, 2009.

(51) Int. Cl. H05K 5/00

(52) U.S. Cl. 361/756

(57) ABSTRACT

Card guide misalignment prevention apparatuses and methods are disclosed for preventing misalignment of cards into a chassis. According an embodiment of one apparatus, a card guide system for facilitating insertion of printed circuit boards (PCBs) into a telecommunications equipment chassis is provided. The card guide system includes a support member for supporting a plurality of pairs of parallel rails extending outward from the support member and across portions of a surface of the support member. Each pair of parallel rails forms a card guide for guiding a PCB across the surface to an electrical connector. The pairs of parallel rails are spaced from each other on the surface. The card guide system also include a plurality of misalignment prevention members extending outward from the surface of the support member between adjacent card guides for preventing PCB misalignment. The support member, rails, and misalignment prevention members are of unitary construction.

### PRIORITY CLAIM

This application claims the benefit of U.S. Provisional Patent Application No. 61/243,996, filed on Sep. 18, 2009, the disclosure of which is incorporated herein by reference in its entirety.

### TECHNICAL FIELD

The subject matter disclosed herein relates generally to card guides. More particularly, the subject matter disclosed herein relates to apparatuses and methods for preventing misalignment when using card guides.

### BACKGROUND

Card-based systems, such as telecommunications equipment chassis, are designed to allow one or more cards or printed circuit boards (“PCBs”) to be inserted into shelves of a chassis. The cards typically include electrical connectors on their leading edges that are inserted into corresponding connectors in the chassis. The electrical connectors in the chassis into which cards are inserted are typically referred to as a plane, such as a mid-plane or backplane. The space limitations involved typically require cards to be inserted carefully and precisely to ensure proper coupling between the cards and the plane and to prevent damage to the plane and the cards.

To ensure proper coupling of cards within the chassis and help prevent damage to expensive equipment, card guides have conventionally been added to aid in card insertion. Card guides generally are slots or spaces between rails aligned so that cards can be slid on an edge or edges until connectors of the cards are inserted into connectors in the chassis (e.g. mid-plane connectors). For instance, a typical chassis or chassis may have holes for inserting card guide rails corresponding to the location of connectors in the chassis. When installing a card using conventional card guides, an edge of the card is placed in between two card guide rails associated with a connector of the plane. The card is moved on its edge until a connector of the card engages the associated plane connector. While conventional card guides direct cards to connectors in the chassis, it is still possible to misalign the cards (e.g., a card installer may overlook or miss the guides and insert the cards without using the guides), and, thus, cause damage to the system or its components. Accordingly, a need exists for apparatuses and methods for preventing card guide misalignment.

### SUMMARY

In accordance with this disclosure, card guide misalignment prevention apparatuses and methods are provided. According to an embodiment of one apparatus, a card guide system for facilitating insertion of printed circuit boards (PCBs) into a telecommunications equipment chassis is disclosed. The card guide system includes a support member for supporting a plurality of pairs of parallel rails extending outward from the support member and across portions of a surface of the support member. Each pair of parallel rails forms a card guide for guiding a PCB across the surface to an electrical connector into which each PCB is inserted. The pairs of parallel rails are spaced from each other on the surface. The card guide system also include a plurality of misalignment prevention members extending outward from the surface of the support member between adjacent card guides for preventing PCB misalignment. The support member, rails, and misalignment prevention members are of unitary construction.

Methods for preventing misalignment of cards into a telecommunications equipment chassis are also disclosed. According to an embodiment of one method, the method includes providing electrical connectors in a telecommunications equipment chassis for engaging PCBs. The method also includes attaching a card guide system to the chassis for facilitating insertion of printed circuit boards (PCBs) into the chassis. The card guide system includes a support member for supporting a plurality of parallel rails extending outward from the support member and across portions of a surface of the support member. Each pair of parallel rails forms a card guide for guiding a PCB across the surface to an electrical connector into which each PCB is inserted. The pairs of parallel rails are spaced from each other on the surface. The card guide system also include a plurality of misalignment prevention members extending outward from the surface of the support member between adjacent card guides for preventing PCB misalignment. The support member, rails, and misalignment prevention members are of unitary construction.

### BRIEF DESCRIPTION OF THE DRAWINGS

A full and enabling disclosure of the present subject matter including the best mode thereof to one of ordinary skill in the art is set forth more particularly in the remainder of the specification, including reference to the accompanying figures, in which:

FIG. 1 is a perspective view of an embodiment of a card guide system according to the present subject matter herein;

FIG. 2 is a perspective view of a card being inserted into a chassis using the card guide system of FIG. 1 according to the present subject matter herein;

FIG. 3 is a side view of an embodiment of a card guide and two misalignment prevention members of the card guide system of FIG. 1 according to the present subject matter herein; and

FIG. 4 is a front view of a card being inserted into a chassis using two card guide systems of FIG. 1 according to the present subject matter herein.

### DETAILED DESCRIPTION

Reference will now be made in detail to the description of the present subject matter, one or more examples of which are shown in the figures. Each example is provided to explain the subject matter and not as a limitation. In fact, features illustrated or described as part of one embodiment can be used in another embodiment to yield still a further embodiment. It is intended that the present subject matter cover such modifications and variations.

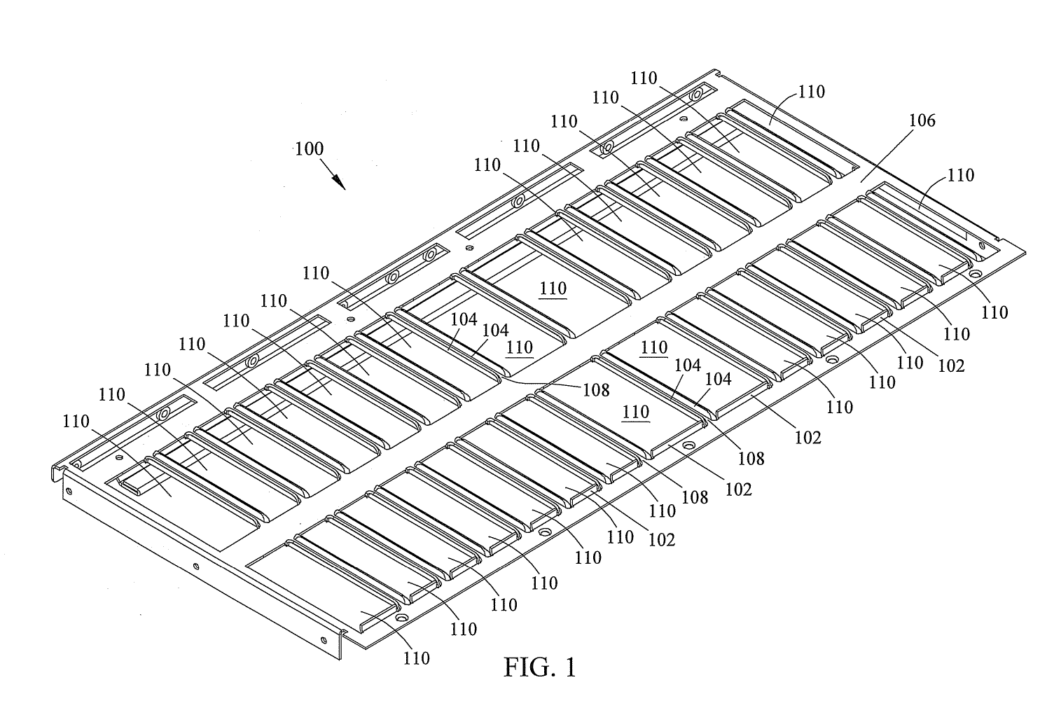

FIG. 1 illustrates one embodiment of a card guide system, generally designated 100, that may be used in association with inserting or installing cards or printed circuit boards (PCBs) into a chassis. As used herein, the terms card and PCB may be used interchangeably and generally refer to any hardware, device, module, or component that connects into a chassis, or to a plane. As used herein, chassis generally refers to framework into which cards can be inserted or mounted. As used herein, plane system or plane generally refers to any hardware, device, module, or component for connecting one or more cards. As used herein, PCB connectors, chassis connectors, chassis connectors, plane connectors, electrical connectors, and any other related connection terminology generally refers to hardware for coupling or connecting cards, planes, chassis, and other devices.

It should be appreciated that various connections (e.g., ‘female’ connections, such as ports, sockets and ‘male’ connectors, such as pins, plugs) and various connection configurations are contemplated. For example, various connectors may be implemented at or on various devices (e.g., ‘male’ connectors at a plane and ‘female’ connectors at a card, ‘female’ connectors at a plane and ‘male’ connectors at a card, or an assortment of connector types for cards, chassis, and planes). Such various connections and configurations may be used without departing from the scope of the subject matter described herein. For illustrative purposes, connection hardware on cards herein will be referred to as PCB connectors and connection hardware in chassis herein will be referred to as chassis connectors and/or plane connectors (e.g., mid-plane connectors, backplane connectors).

Card guide system 100 may include one or more card guides 108 and one or more misalignment prevention members (MPMs) 102. Card guides 108 are for guiding cards, and particularly cards' PCB connectors, into connectors in a chassis (e.g., mid-plane connectors, backplane connectors, or other connectors). In one embodiment, each card guide 108 includes a surface substantially bordered on two sides by rails 104. In one embodiment, a card guide 108 may include a pair of parallel rails 104 that extend outward from a surface of a support member 106 for guiding a PCB across the surface of support member 106 to an electrical connector into which each PCB is inserted. The pairs of parallel rails may be spaced from each other on the surface. Rails 104 may be any size or shape (e.g., slightly bowed or curved at edges). Rails 104 may include one or more discontinuities on the surface of the support member (e.g., portions of rails 104 may appear or be flat). Rails 104 may include a variety of structures for providing support or guidance for guiding a card along the surface of support member 106 between card rails 104. For example, rails 104 may include any combination of clamps, raised edges, tabs, ridges, grooves, tensioned lines, wires, and strings. As shown in FIG. 1, each card guide 108 provides a path for an edge of a card to move (e.g., towards a plane or away from a plane).

MPMs 102 are for preventing card misalignment. For example, MPMs 102 may prevent or minimize damage to a plane, card, or other device (e.g., prevent a misaligned card from damaging connection pins, connection receptacles, or circuitry components). In one instance, one or more MPMs 102 may prevent insertion of PCBs into the electrical connectors of the chassis between card guides 108. In some embodiments, MPMs 102 may be raised edges or tabs extending outward from a surface of support member 106 between card guides 108. In alternate embodiments, MPMs 102 may include additional or alternate alignment support structures, such as clamps, rails, tabs, ridges, grooves, tensioned lines, wires, and strings. In the embodiment shown in FIG. 1, a plurality of MPMs 102 is shown extending outward from the surface of support member 106 between adjacent card guides for preventing PCB misalignment. In one embodiment, the tabs of MPMs 102 may be long and/or high enough to hinder or prevent a card from being incorrectly inserted into an electrical connector. In some embodiments, preventing a card from being improperly inserted may include requiring the card to be inserted using a card guide 108. In the embodiment shown in FIG. 1, the tabs of MPMs 102 facilitate inserting PCBs between pairs of rails 104 of card guide system 100.

Support member 106 may have a substantially planar surface, other than rails 104 and MPMs 102. Support member 106 may provide support (e.g., structural support) to card guide system 100 and/or components of card guide system 100.

Card guide system 100 may include one or more holes or apertures 110. In one embodiment, apertures 110 are formed by extracting or removing one or more portions of support member 106 (e.g., punching holes in sheet metal). Each rail 104 may be adjacent to an aperture 110. Each MPM 102 may be adjacent to an aperture 110 and may extend in a direction transverse to each rail 104. MPMs 102 and/or the rails 104 may be formed by bending outwards edges of support member 106 that forms sides of each aperture 1110. For example, MPMs 102 and/or card rails 104 may be formed by bending portions of support member 106 upwards, outwards, and/or at various angles from one or more portions of support member 106.

In the embodiment shown in FIG. 1, support member 106 is shown for supporting a plurality of pairs of parallel rails 104 extending outward from support member 106 and across portions of a surface of the support member 106. Support member 106 may include securing features, such as holes, overhangs, lips, brackets, indentions, and/or other like features, used in securing card guide system 100 in or to a plane chassis (e.g., a telecommunications equipment chassis). For example, screws, bolts, pins, ties, clips, and/or fasteners may be used for securing card guide system 100 to a media gateway chassis. Additional components or portions of card guide system 100 may include similar features. For example, support member 106 may include additional surfaces, sides, edges, or portions for securing card guide system 100. Such surfaces may extend in various ways or directions and may include one or more securing features.

Card guide system 100, including components of card guide system 100, may be fabricated from any suitable rigid materials, including metals, metal alloys, rigid plastics, etc., using any suitable fabrication processes, including welding, machining, molding, casting, stamping, bending, punching, and pressing. Components of card guide system 100, including card guide rails 104, MPMs 102, and support members 106, may be fabricated using the same materials and/or same fabrication processes. Alternatively, different components or portions of card guide system 100 may be fabricated using different materials and/or fabrication processes. For example, a support member 106 may be fabricated using high-grade aluminum and card guide rails 104 may be fabricated using polytetrafluoroethylene-coated (e.g., Teflon®-coated) plastic. In one embodiment, card guide system 100 may be formed with components, such as an MPM 102 and rails 104, attached (e.g., glued, fastened, or wielded) to a base portion or support member 106.

In one embodiment, card guide rails 104, MPMs 102, and support members 106 may be of unitary construction. For example, support member 106 may a unitary sheet of metal, and MPMs 102 and rails 104 may be formed by bending outwards portions of the unitary sheet of metal. In another example, support member 106, MPMs 102, and rails 104 may be formed by using a molding or rapid prototyping process.

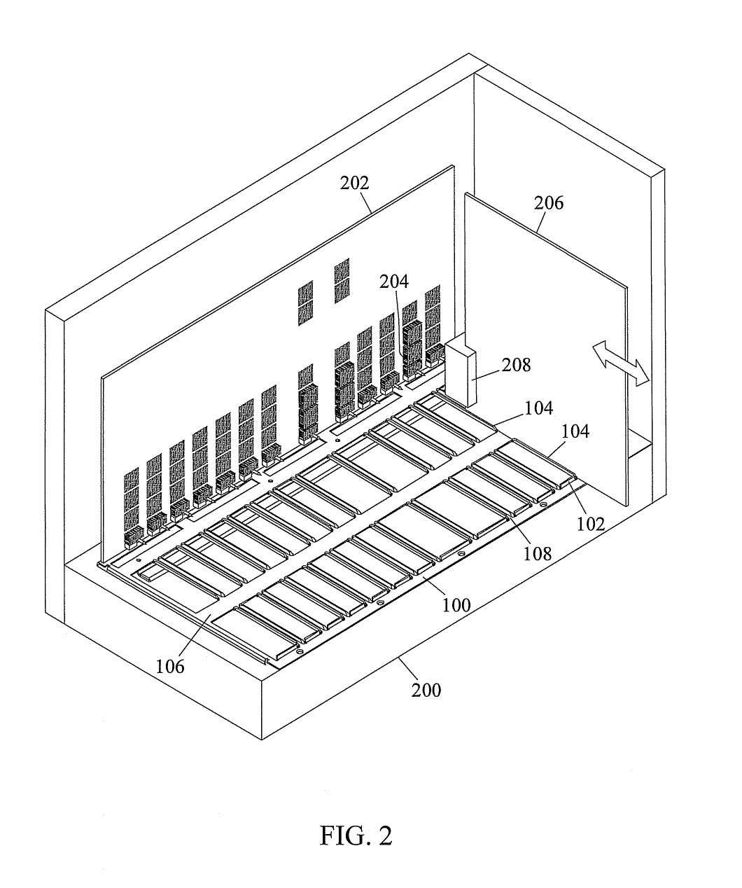

FIG. 2 illustrates a card 206 being inserted into a telecommunications equipment chassis 200, such as a chassis of a media gateway, gateway controller, session border controller, or an element management system. As shown in the embodiment of FIG. 2, a plane 202 is attached to chassis 200 and includes electrical connectors, also known as chassis or plane connectors. Card 206 includes a PCB connector 208 for connecting or engaging a plane connector 204. Card 206 may provide a service or function for telecommunications equipment (e.g., card may provide a network interface function or a digital signaling processing (DSP) function). Plane 202 represents a circuit board (e.g., a PCB) for connecting several cards 206 together. Depending on the usage and/or configuration, plane 202 may be referred to as various devices, including a backplane, mid-plane, or motherboard. For example, a plane 202 may be referred to as a backplane if cards or devices connect to one side of plane 202 and may be referred to as a mid-plane if cards or devices connect on two sides of plane 202.

In FIG. 2, card 206 is being inserted into chassis 200 using a card guide 108 of card guide system 100. As shown in the embodiment of FIG. 2, card guides 108 correspond to the location of plane connectors 204. When installing or inserting card 206 into plane 202, an edge of card 206 is placed in between two card guide rails 104 associated with plane connector 204. Using card guide 108, card 206 may be moved or slid on its edge until PCB connector 208 engages plane connector 204 or vice versa.

As noted above, it is desirable for cards 206 to be properly inserted into chassis 200. As such, MPMs 102 may be used to prevent improper insertion of cards and/or prevent damaging to chassis 200 or plane 202. In the embodiment shown in FIG. 2, one or more MPMs 102 facilitates use of card guides 108. For example, insertion of a card 206 may be attempted at a MPM 102 but hindered or prevented by a raised edge or tab. The tab of MPM 102 may be any size and shape to prevent card 206 from moving forward (i.e., towards connectors of plane 202). To avoid MPM 102 (e.g., overcome the height of the tab), an installer may attempt to raise and insert card 206 above MPM 102. In one embodiment, tab of MPM 102 is high enough to prevent a card's PCB connector 208 from engaging a plane connector 204. An additional or alternative feature of MPM 102 may include the top of card 206 meeting a barrier (e.g., a shelf or component that is located above card guide system 100) if card 206 is attempted to be inserted above MPM 102. Hence, MPMs 102 may be used to prevent improper insertion of card 206 into plane 202. While FIG. 2 depicts MPM 102 including a raised edge or tab, it should be appreciated by one of ordinary skill in the art that any support or guidance structures may be used to prevent card misalignment and/or prevent damage to plane 202. For example, MPM 102 may include one or more clamps, raised edges, tabs, rails, ridges, grooves, tensioned lines, wires, and strings.

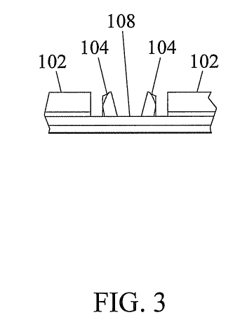

FIG. 3 illustrates a card guide 108 and two MPMs 102 of card guide system 100. In particular, FIG. 3 depicts a front section of card guide system 100 where a card may be place in card guide 108 between rails 104. Rails 104 may help direct the card along its edge (e.g., towards a plane connector of a plane or away from the plane connector). In the embodiment shown in FIG. 3, MPMs 102 include tabs extending outward from the surface of card guide system 100 for preventing a card from being inserted into a plane without using card guide 108. In one embodiment, MPMs 102 are taller than rails 104 of card guide 108. In an alternative embodiment, MPMs 102 are the same height or shorter than rails 104. In the embodiment shown in FIG. 3, MPMs 102 are about the same height as rails 104. In one embodiment, space exists between MPMs 102 and rails 104. In this embodiment, space between MPMs 102 and rails 104 may be less than the width, depth, or other dimension of a card. By limiting the amount of space between MPMs 102 and rails 104, the likelihood that cards will be misaligned is reduced (e.g., a card may not fit in a gap between a MPM 102 and a rail 104 that is smaller than the width of the card's edge). Hence, small spaces between MPMs 102 and rails 104 may prevent cards from being inserted without using a card guide 108. In an alternative embodiment, MPMs 102 and rails 104 meet, touch, or are adjoined in such a way that no space is between MPMs 102 and rails 104.

It will be appreciated that multiple card guide systems 100 or portions thereof may be attached to or used in a telecommunications equipment chassis 200. In some embodiments, a chassis may include multiple card guide systems 100 for connecting PCBs 206 to electrical connectors 204 that are of various types and/or arrangements, such as groups, rows, stacks, racks, or shelves. For example, telecommunications equipment chassis 200 may include a mid-plane 202 where a first side of mid-plane 202 includes connectors 204 for accepting voice processing cards (e.g., DSP cards) and a second side of mid-plane 202 include connectors 204 for accepting network interface cards (NICs). Each side may have one or more card guide systems 100. In a second example, a chassis may include a plurality of shelves for PCBs 206. In this example, the chassis 200 could include multiple plane systems 202 at different heights or one or more planes 202 with stacked connectors 204. Each shelf may have one or more card guide systems 100. For example, a shelf may have a group of plane connectors 204 for connecting cards 206. A first card guide system 100 may be attached at or near the bottom of the shelf for guiding a bottom portion of cards 206 and a second card guide system 100 may be attached at or near the top of the shelf for guiding a top portion of cards 206.

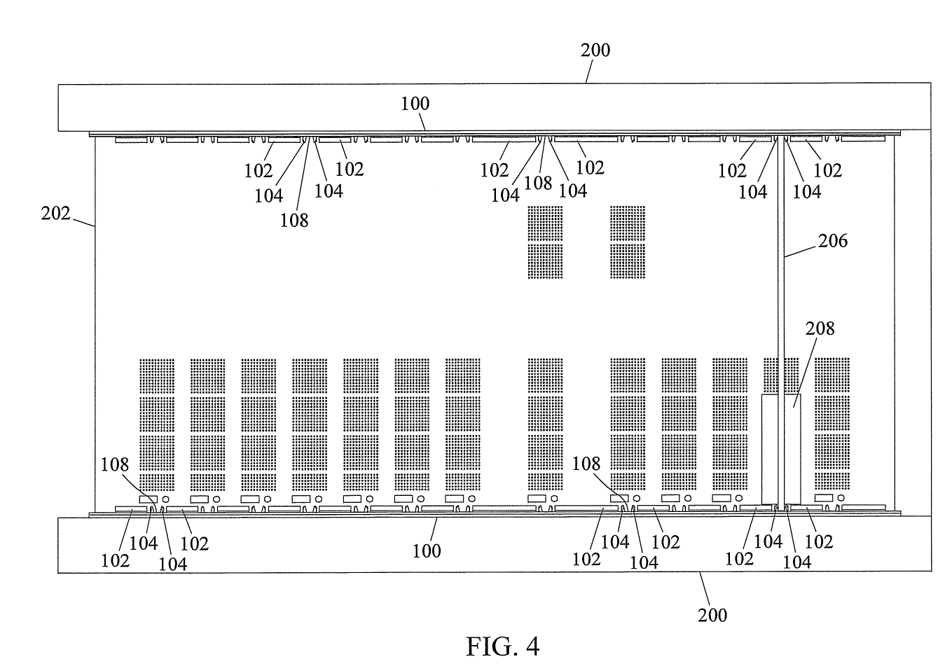

FIG. 4 illustrates a card 206 being inserted into a telecommunications equipment chassis 200 using two card guide systems 100. As shown in the embodiment of FIG. 2, a plane 202 is attached to chassis 200 and includes electrical connectors, also known as chassis or plane connectors. Card 206 includes a PCB connector 208 for connecting or engaging an electrical connector in the chassis 200. Card guide system 100, including card guides 108, correspond to the location of electrical connectors in the chassis 200. For example, a first card guide system 100 may be attached substantially at or below electrical connectors in the chassis 200 (e.g., connectors of plane 202) and an inverted second card guide system 100 may be attached substantially at or above electrical connectors in the chassis 200 (e.g., connectors of plane 202). The first and second card guide systems 100 may be aligned such that card guides 108 from top card guide system 100 and card guides 108 from bottom card guide system 100 guide cards 206 to electrical connectors in the chassis 200 (e.g., connectors of plane 202).

In the embodiment shown in FIG. 4, first card guide system 100 is attached above the electrical connectors in chassis 200 and second card guide system 100 is attached below the electrical connectors in chassis 200. A card guide 108 from first card guide system 100 is aligned to guide a top edge of card 206. A corresponding card guide 108 from second card guide system 100 is aligned to guide a bottom edge of card 206. The alignment is such that connector 208 of card 206 engages an electrical connector in the chassis 200. MPMs of first and second card guide systems 100 prevent the top and bottom edges of card 206 from being misaligned.

Embodiments of the present disclosure shown in the drawings and described above are exemplary of numerous embodiments that can be made within the scope of the appending claims. It will be understood that various details of the subject matter described herein may be changed without departing from the scope of the subject matter described herein. Furthermore, the foregoing description is for the purpose of illustration only, and not for the purpose of limitation, as the subject matter described herein is defined by the claims as set forth hereinafter.

What is claimed is:

1. A card guide system for facilitating insertion of printed circuit boards (PCBs) into a telecommunications equipment chassis, the card guide system comprising:
a support member for supporting a plurality of pairs of parallel rails extending outward from the support member and across portions of a surface of the support member, wherein each pair of parallel rails forms a card guide for guiding a PCB across the surface to an electrical connector into which each PCB is inserted, the pairs of parallel rails being spaced from each other on the surface; and
a plurality of misalignment prevention members extending outward from the surface of the support member between adjacent card guides for preventing PCB misalignment, wherein the support member, rails, and misalignment prevention members are of unitary construction.

2. The card guide system of claim 1, wherein the support member facilitates insertion of the PCBs into mid-plane connectors in the chassis.

3. The card guide system of claim 1, wherein the support member facilitates insertion of the PCBs into back-plane connectors in the chassis.

4. The card guide system of claim 1, wherein the support member, rails, and misalignment prevention members are fabricated from sheet metal.

5. The card guide system of claim 4, wherein the rails and the misalignment prevention members are formed by bending portions of the support member.

6. The card guide system of claim 1, wherein each pair of rails extends outward at an angle from the support member.

7. The card guide system of claim 1, wherein each pair of parallel rails includes a discontinuity on the surface of the support member.

8. The card guide system of claim 1, wherein the support member includes a plurality of apertures and wherein each rail is adjacent to an aperture.

9. The card guide system of claim 8, wherein each misalignment prevention member is adjacent to an aperture and extends in a direction transverse to each rail.

10. The card guide system of claim 8, wherein the misalignment prevention members and the rails are formed by bending outwards edges of the support member that form sides of each aperture.

11. A telecommunications equipment chassis:
electrical connectors located in the chassis; and
a first card guide system attached to the chassis for facilitating insertion of printed circuit boards (PCBs) into the chassis, wherein the first card guide system includes a support member for supporting a plurality of parallel rails extending outward from the support member and across portions of a surface of the support member, wherein each pair of parallel rails forms a card guide for guiding a PCB across the surface to an electrical connector into which each PCB is inserted, the pairs of parallel rails being spaced from each other on the surface, and a plurality of misalignment prevention members extending outward from the surface of the support member between adjacent card guides for preventing PCB misalignment, wherein the support member, rails, and misalignment prevention members are of unitary construction.

12. The chassis of claim 11 comprising:
a second card guide system attached to the chassis for facilitating insertion of printed circuit boards (PCBs) into the chassis.

13. The chassis of claim 12, wherein the first card guide system is attached above the electrical connectors in the chassis and the second card guide system is attached below the electrical connectors in the chassis, wherein a card guide from the first card guide system is aligned to guide a top edge of a PCB and a corresponding card guide from the second card guide system is aligned to guide a bottom edge of the PCB such that a connector of the PCB engages an electrical connector in the chassis, wherein misalignment prevention members of the first and second card guide systems prevent the top and bottom edges of the PCB from being misaligned.

14. A method for preventing misalignment of cards into a telecommunications equipment chassis, the method comprising:
providing electrical connectors in a telecommunications equipment chassis for engaging PCBs; and
attaching a card guide system to the chassis for facilitating insertion of printed circuit boards (PCBs) into the chassis, wherein the card guide system includes a support member for supporting a plurality of parallel rails extending outward from the support member and across portions of a surface of the support member, wherein each pair of parallel rails forms a card guide for guiding a PCB across the surface to an electrical connector into which each PCB is inserted, the pairs of parallel rails being spaced from each other on the surface, and a plurality of misalignment prevention members extending outward from the surface of the support member between adjacent card guides for preventing PCB misalignment, wherein the support member, rails, and misalignment prevention members are of unitary construction.

15. The method of claim 14 comprising:
attaching a second card guide system to the chassis for facilitating insertion of printed circuit boards (PCBs) into the chassis.

16. The method of claim 15, wherein the first card guide system is attached above the electrical connectors in the chassis and the second card guide system is attached below the electrical connectors in the chassis, wherein a card guide from the first card guide system is aligned to guide a top edge of a PCB and a corresponding card guide from the second card guide system is aligned to guide a bottom edge of the PCB such that a connector of the PCB engages an electrical connector in the chassis, wherein misalignment prevention members of the first and second card guide systems prevent the top and bottom edges of the PCB from being misaligned.
